(19) United States
(12) Patent Application Publication
(10) Pub. No.: US 2017/0360223 A1
(43) Pub. Date: Dec. 21, 2017

(54) Construction Plate and Modular Storage and Display System Assembled Therefrom

(71) Applicants: Josh Rifkin, Cardiff, CA (US); Chris Clemmer, Ft. Collins, CO (US); David Bowen, Ft. Collins, CO (US)

(72) Inventors: Josh Rifkin, Cardiff, CA (US); Chris Clemmer, Ft. Collins, CO (US); David Bowen, Ft. Collins, CO (US)

(21) Appl. No.: 15/731,496

(22) Filed: Jun. 19, 2017

Related U.S. Application Data
(60) Provisional application No. 62/493,032, filed on Jun. 20, 2016.

(51) Int. Cl. A47F 5/10; F16B 5/00; A47F 5/02; A47F 7/00; H05K 7/10; H05K 5/00

(52) U.S. Cl. CPC A47F 5/10; H05K 7/10; H05K 5/0017; A47F 5/02; A47F 7/00; F16B 5/0084

(57) ABSTRACT

The present invention is a construction plate and system made of a series of construction plates. The construction plate is a flat sheet of generally square or rectangular material having a length to width ratio of particular dimensions with at least one opening about its center having slots along the top and bottom edges for connecting the construction plates together. The construction plate may additionally have indentations along the top edge for integrating with other construction plates, slots on the left and/or right side edges for receiving other construction plates, apertures near the corner of the top edge and left side and/or right side edges and near the corner of the bottom edge for receiving dowels or poles for hanging items and the at least one opening and/or top edge of the flat sheet may have keyhole shaped apertures extending toward said bottom edge of said flat sheet.

### CROSS-REFERENCE TO RELATED APPLICATIONS

This application is a continuation in part application of U.S. patent application Ser. No. 62/493,032 filed on 20 Jun. 2016 which is incorporated herein in its entirety by this reference.

### STATEMENT REGARDING FEDERALLY SPONSORED RESEARCH OR DEVELOPMENT

Not applicable

### THE NAMES OF THE PARTIES TO A JOINT RESEARCH AGREEMENT

Not applicable

### INCORPORATION-BY-REFERENCE OF MATERIAL SUBMITTED ON A COMPACT DISC

Not applicable

### TECHNICAL FIELD

The present invention is a system for erecting modular, weight-bearing walls, shelves, and table-tops without the use of any tools, which stacks flat into a manageable box that can be rolled and assembled by one person. The purpose of this product is to provide a stable structure to display a wide range of products that sit on shelves, tables and free standing pedestals as well as hang from hooks and garment poles. This display booth provides a way to emulate a retail shopping experience where physical products are sold on varying display mediums. With simple clean aesthetics, this display booth offers a blank canvas for exhibitors to let their product, branding and color themes do the selling. The walls and display features are comprised of flat plate materials such as wood, plastic and/or composite materials that that piece together to create a stable structure. The parts fit together by inserting hooked tabs into slots that fit the width of the tabs. Since all the parts are interchangeable, the system allows for multiple configurations, as well as easy expansion of the display booth by adding more parts. Additionally, since the plates are all flat, they stack on top of each other for easy storage, set up and dismantle.

### BACKGROUND OF THE INVENTION

Trade shows are a common means for vendors to advertise their goods and services to the trade. These shows are held worldwide and attract vendors, buyers, and resellers from all over the world. Large sums of money are spent by vendors to display their products in an eye catching manner. Generally, the vendor either purchases or makes a display booth and ships it to the trade show where it is assembled. After the show, the display booth is disassembled and shipped back to the vendor's place of business or an outside contractor where it is stored until the next trade show. It is not uncommon for a vendor to attend multiple trade shows annually.

The display booths commonly available are not only expensive to purchase or rent, but they also are extremely costly to construct, ship, assemble, disassemble, and store. The extreme ongoing expense associated with these standard display booths is due to their weight and large size. Standard display booths are often constructed of heavy, large format materials (such as sheets of plastic, acrylic and metal), in addition to heavy frame structures, and require screws, staples, pins, and metal rods to assemble, which requires hired union labor that is extremely expensive. While some display booths may be condensed for shipment, they generally must be shipped on multiple large pallets.

Although others have invented knock-down, flat pack or tab-and-slot construction products, this invention is superior because it: may be comprised of light-weight materials, thereby reducing shipping and drayage costs associated with standard display booths; may be comprised in such a way that the pieces all lay flat on top of each other for easy storage and transport, thereby reducing shipping and drayage costs associated with standard display booths; may be comprised in such a way that the display booth requires no tools or screws to assemble, thereby eliminating the need for union labor and providing a substantial savings; may be comprised in such a way that the display booth fits in a box that can also function as a table or podium within the booth, for both functionality and easy access; may provide a stable structure to support the display of physical product unlike other pop-up booths that only provide a printed fabric wall; may be comprised in such a way that offers several merchandizing options for displaying product within the booth; may be comprised in such a way that offers several branding options, such as different skins that may consist of plastic, metal, carbon fiber, wood and other materials that come in different colors and patterns; may be comprised in such a way that the same structural slotting can serve as a means for sliding banners with the same dimensional thickness as the flat plates for the purpose of increasing the brand awareness. This could be accomplished by using material like gator board, or foam core printing materials. The banner would slot in and stand tall above the structure providing a stable base for vertical and horizontal printing options; may be comprised in such a way that the same structural slotting can serve as a means for securing wood dowels into a slotting with an l or t shape to secure one dowel on the bottom of the structure and one at the top. Both of the dowels would be connected to a fabric that could be used to print on for branding purposes. The top and bottom dowels would stretch and fasten into the cutouts in the plates to create an easy to store and easy to assemble vertical branding option; may be comprised in such a way that the same structural slotting can serve as a means for sliding shelves onto the columns of the structure. This would allow for the supports to become a merchandising option as well. The slots would be spaced out to allow the client to choose the amount of shelves they need; may be comprised in such a way that allows for flat paneled components to fit on to the structural tabs for the purpose of concealing the inner workings of the structure. This will provide a clean flat plate on the front for branding and the recessed extrusions on the back of the plate will match up with the tabs for a snug fit; and may be comprised in such a way that is modular so that the configuration of the display booth is modifiable and can be easily expanded.

The present invention is a construction plate that when assembled with other construction plates can create organizational display or storage system having towers with slat walls, banner displays or shelving between them as well as table tops and pedestals integrated therewith. The construction plate is a flat sheet of generally square or rectangular material having a length to width ratio of about 0.5:1.0, about 1.0:1.0, about 1.0:2.0 or about 1.0:5.0. Each construction plate has a top edge, a bottom edge, a left side edge, a right side edge, a left side, a right side, a top side and a bottom side, wherein the flat sheet has at least one opening about its center that is square or rectangular in shape and is of a size that occupies about 10% to about 30% of the area of said flat sheet. The top edge has at least two elongated slots near the left and right side edges. The slots are about the same thickness as the flat sheet and have a length of about 1/10 to about ½ the length of the flat sheet. The top edge may have X number of indentations with a depth of about the thickness of the flat sheet and a length of about ¼ to about ⅓ the width of the top edge, wherein X=0 or 1. The bottom edge may have Y number of elongated slots near the left and right side edges. The slots are about the same thickness as the flat sheet and have a length of about 1/10 to about ½ the length of the flat sheet, wherein Y=0 or 2. The left side edge and right side edge independently may have Z number of slots. The slots being the same thickness as the flat sheet and having a length of about 1/20 to about ⅕ the width of the flat sheet, wherein Z=0, 1, 2, 3, 4, 5, 6, 7, 8, 9 or 10. The left side and right side independently have P number of apertures near the corner of the top edge and the left side and/or right side edges and near the corner of the bottom edge and the left side and/or right side edges, wherein said apertures are from about 2.0 cm to about 6.0 cm and wherein P=0 or 1. The at least one opening may have Q number of keyhole shaped apertures extending toward the bottom edge of the flat sheet, wherein Q=0, 1 or 2 and the top edge may have R number of keyhole shaped apertures extending toward the bottom edge of the flat sheet, wherein R=0 or 1.

In one embodiment the construction plate may further comprise an electrical system, wherein the electrical system has an inlet for receiving electrical current, one or more plug elements for connecting devices to the construction plate that require electricity to operate and an outlet for electrical connectivity with one or more other construction plates. The electrical system may further comprise one or more controllers, routers, antennas, data communications relay systems and/or WiFi connectivity hubs.

In another embodiment the construction plate may further comprise one or more lights or one or more speakers, wherein the one or more lights or one or more speakers are affixed to or integrated within the plate.

In yet another embodiment the construction plate may further comprise an electrical system having one or more adapters for connecting one or more desk top computers, one or more laptop computers, one or more tablets, one or more cellular phones, one or more battery chargers, one or more extension cords or one or more surge protectors.

In still another embodiment the construction plate may further comprise a magnetically susceptible surface or have one or more magnets embedded within the plate or have one or more translucent covers that fit within at least one opening of the plate.

Another aspect of the present invention is an organizational storage or display system comprising a plurality of construction plates that are connected together in a desired configuration at 90 degrees to one another by slot in slot connectors. The organizational storage or display system may have: S number of table tops, wherein the edges of the table top are inserted into a Z slot of a construction plate, wherein S=0 to 5; T number of pedestal tops, wherein the pedestal tops have at least four apertures or groove indentations, wherein the apertures or groove indentations have a length of about 2.5 to about 7.5 centimeters and a width slightly larger than the thickness of the construction plate, the region between any two apertures that have a common axis to be received by the X indentations of a construction plate, wherein T=0 to 10; N number of shelves, wherein the shelves have a front end, a back end, a left side and a right side, wherein each of the sides contains a notched adapter, wherein the notch is slightly larger than the thickness of the construction plate, wherein the notched adapter fits through the at least one opening and engages the edges of the at least one opening orienting the shelf in a horizontal orientation parallel with the ground, wherein N=0 to 30; M number of slat wall supports, wherein the slat wall supports have a groove along its length and affixed to the construction plate so that the slat wall support is oriented perpendicular to the ground, wherein M=0, 2, 4, 6, 8 or 10; and K number of wall slats, the wall slats having a thickness slightly thinner than the groove in the slat wall supports, wherein K=2 to 100.

In one embodiment of this aspect of the invention the organizational storage or display system may further comprise J joice supports. The joice supports have an upper side, a lower side, a first end side and a second end side, with at least two notches on its lower side for receiving the top edge of the construction plate, wherein J=0 to 10.

In another embodiment the table top or the pedestal top may further comprise a revolving platform, such as a Lazy Susan. The invention may be better visualized by turning now to the following drawings.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to the similar parts, and in which:

FIG. 1: illustrates a perspective view of one configuration of a 5 foot by 10 foot display booth.

FIG. 2: illustrates some of the construction plate configurations that may be assembled in a variety of desired structures to create a display or storage system.

FIG. 3: illustrates a perspective view of one configuration of a 20 foot by 10 foot display booth.

### DETAILED DESCRIPTION OF THE INVENTION

Unless defined otherwise, all terms used herein have the same meaning as are commonly understood by one of skill in the art to which this invention belongs. All patents, patent applications and publications referred to throughout the disclosure herein are incorporated by reference in their entirety. In the event that there is a plurality of definitions for a term herein, those in this section prevail.

The term “plate” and/or “panel” as used herein refer to the construction plate of the present invention.

The present invention is a system for erecting modular, weight-bearing walls, shelves, and table-tops without the use of any tools, which stacks flat into a manageable box that can be rolled into a convention and assembled by one person. The parts fit to together by inserting hooked tabs into slots that fit the width of the tabs.

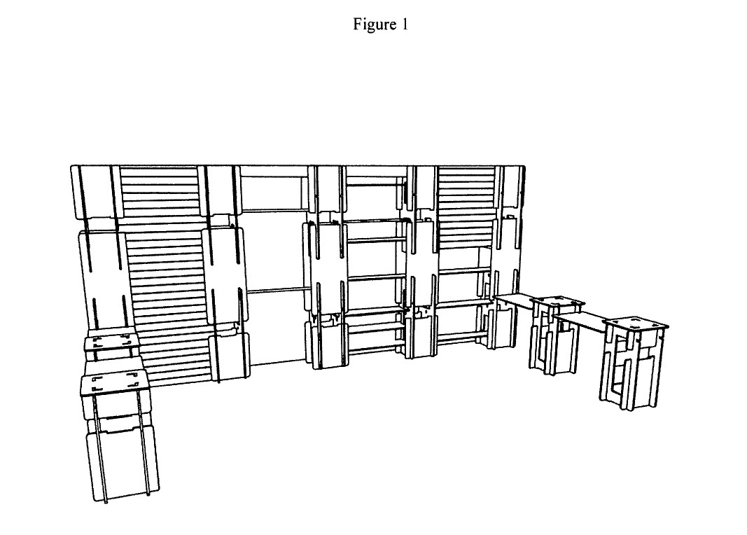

With the above in mind, attention is now directed to FIG. 1, which reveals that the display booth's structure is composed of interlocking flat panels that collectively, when pieced together, provide a stable structure for displaying product and/or sales materials. When the structure is erected after fitting the tabs into opposing slots, the columns provide a stable back wall and the shorter columns provide a stable tabletop surface. In addition, printed fabrics and/or skins can be hung from the walls and/or framed out by the skeletal structure. Illustrations of the panel skins fit on to the structural tabs for the purpose of concealing the inner workings of the structure. This will provide a clean flat panel on the front for branding and the recessed extrusions on the back of the panel will match up with the tabs for a snug fit. The display booth essentially does not have a back or front and is aesthetically pleasing from all angles. This is a critical point of differentiation between most trade show booths in the market and provides a more diverse benefit of display capabilities. The entry point of the booth is composed of interlocking flat panels that collectively, when pieced together, provide a stable structure for displaying product or sales materials as well as places for hanging printed fabric for increasing brand awareness or highlighting images of new product. In addition, there are multiple tabletop features for displaying product as well as locations for hanging shelving from the walls of the display booth. Additionally, the containers that house the display booth can be used as display structures, as seen in the middle of the display booth (not in the illustration).

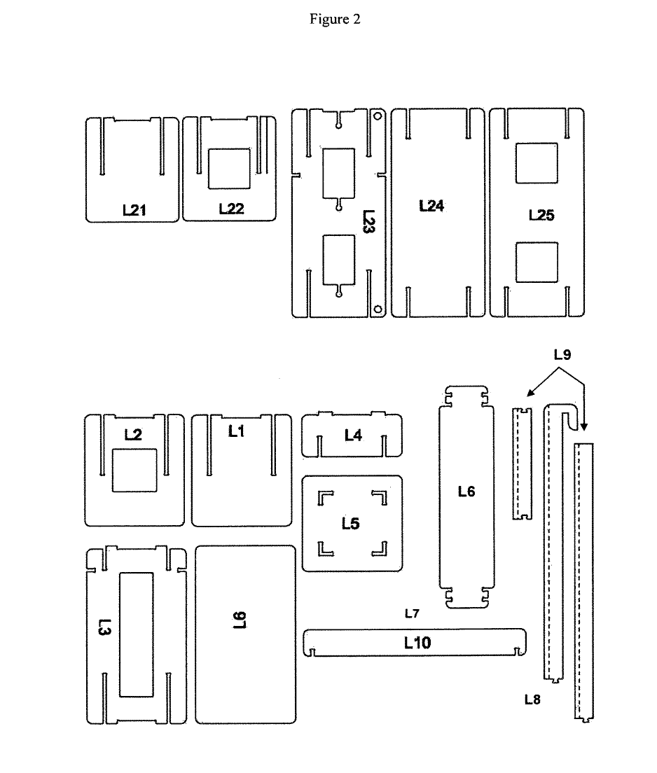

FIG. 2 shows possible configurations for the construction plate that may be assembled to create display structures similar to that shown in FIG. 1. They may also be used to construct systems that may be utilized for storage in a large commercial warehouse or a private garage. While not being limited to these particular configurations, the construction plates identified as L21 through L25 may be utilized to construct the central and side towers that provide the height for a display or storage system while the construction plates identified by L1 through L7 may be utilized to construct table tops on which the user may work and/or pedestals for displaying items. The construction plate L10 may be used to connect one tower to another while providing additional structural support and adapters L8 and L9 may be used to create wall panels, wherein wall slats are slid into grooves shown by the dotted lines on these adapters. The plates are pictured in the orientation in which they will be more elaborately discussed below. More specifically the top of the plate is oriented to the top of the figure, the bottom of the plate is oriented to the base of the figure, the left side edge of the plate faces the left side of the figure and the right side edge of the plate faces the right side of the figure.

In FIG. 2, construction plate L1 is of generally square configuration with a length to width ratio of about 1.0:1.0 having two elongated slots extending downward from the top edge near the left and right side edges having a width of about the thickness of the construction plate and a length of about one-half the length of the plate. There is an indentation about centered on the top edge having a length of about one-third the length of the top edge and a depth of about the thickness of the plate. This indentation may be used to interface with a shelf such as L7. Construction plate L2 is similar to L1 and further comprises an opening about the center of the plate and having the general shape of a square. Construction plates L21 and L22 are similar and may be identical to L1 and L2.

Construction plate L3 is rectangular in shape with a length to width ratio of about 2.0:1.0 having two elongated slots extending upward from the bottom edge near the left and right side edges having a width of about the thickness of the construction plate and a length of about one-third to one-fourth the length of the plate. In addition, there is a rectangular opening about the center of the plate. Further, there is an indentation centered on the bottom edge having a length of about one third the length of the bottom edge and a depth of about the thickness of the plate. There are two slots extending downward from the top side having a width of about the thickness of the plate and a length of about one seventh to about one ninth the length of the plate. There are two slots near the top of the plate extending parallel to the top edge of the plate, one on each of the left and right side edges having a width of about the thickness of the plate and a length of about one-ninth to about one twelfth the width of the plate. This slot may be used to interface with a table top, such as L6. In addition, the top edge has two knobs that extend upward to a height about the thickness of the plate or about one-half the thickness of the plate, having a length of about one-ninth to about one twelfth the width of the plate. Each knob has one edge being integral with the slot next to its location. These knobs may be used to integrate with a pedestal top, such as L5.

Construction plate L4 is rectangular in shape with a length to width ratio of about 1.0:2.0 having two elongated slots extending upward from the bottom edge near the left and right side edges having a width of about the thickness of the construction plate and a length of about one-half the length of the plate. In addition, the top edge has two knobs that extend upward to a height about the thickness of the plate or about one-half the thickness of the plate, having a length of about one-fourth to about one seventh the width of the plate. Each knob is oriented on the top edge at a distance from the left and right side edges that is equal to the knob's length. These knobs may be used to integrate with a pedestal top, such as L5.

Construction plate L5 is about square in shape with a length to width ratio of about 1.0:1.0 having four L-shaped apertures or indentations positioned about the middle of the plate. These L-shaped apertures or indentations have a width of about the thickness of the construction plate and a length of about one-fourth to about one seventh the width of the plate.

Construction plate L6 is generally an elongated rectangular shape with a length to width ratio of about 4.0:1.0 each end having an interlocking portion that when tilted fits through and locks into the opening provided for example in L2, L3, L22, L23 and L25. Each end of L6 has four locking slots or two pairs of locking slots with each pair being able to receive the edges of the opening in a construction plate. The purpose for the locking slots is to enable the user to expand or contract the length or width of an organizational or display system before or during use. One configuration of these slots is shown in FIG. 2.

The construction plates L1 through L6 may be utilized to create table tops and pedestal stands.

Construction plate L7 is generally an elongated rectangular shape having a length to width ratio of about 7.0:1.0 with slots provided on the bottom near the left side and right side edges. These slots have a width of about the thickness of a construction plate and a length of about one-fourth to about one-third the width of the construction plate. This construction plate may be added to the top of a organization storage or display system to add additional stability.

Construction plate L8 and extender plates L9 are elongated slatwall adapters for an organization storage or display system. FIG. 2 shows a side view of L8 having a hook on one end for interacting with the top of a construction plate and a dove tail or similar connection on the other end for attaching extension pieces L9. The dotted line indicates a groove provided along the edge opposite the hook having a thickness to be able to receive slats to create a slatwall. Extended pieces L9 can have on one or both ends, a dove tail or similar connector for interfacing with the mated end of L8. These extenders also have a groove on one or both sides that are of a thickness to be able to receive slats to create a slatwall. Construction plate L8 allows the user to create a half wall while the L9 extenders allow the user to extend the wall to the floor depending on the height of the organizational storage or display system.

Construction plates L6 through L9 are generally accessory elements for integration into the wall column construction plates L21 through L25 to create shelving, slat walls or add additional structural integrity to the organizational storage or display system.

Construction plate L23 is rectangular in shape with a length to width ratio of about 2.5:1.0 having two elongated slots extending upward from the bottom edge near the left and right side edges having a width of about the thickness of the construction plate and a length of about one-third to one-fourth the length of the plate. In addition, there are two rectangular openings about the center of the plate about equidistant from each other. Further, there is an indentation about centered on the top edge having a length of about one-third the length of the bottom edge and a depth of about the thickness of the plate. There are two slots extending downward from the top side having a width of about the thickness of the plate and a length of about one seventh to about one-third to about one-fourth the length of the plate. There are two slots near the top of the plate extending parallel to the top edge of the plate, one on each of the left and right side edges having a width of about the thickness of the plate and a length of about one-ninth to about one-twelfth the width of the plate. This slot may be used to interface with a table top, such as L6. In addition, the top and bottom edges on the right side of the plate have an aperture of about 1 inch to about 2.5 inches in diameter able to receive a dowel or clothes rod. There are also three keyhole apertures extending from about the center of the base of each opening and one from the top edge positioned shout the middle of the indentation.

Construction plate L24 is rectangular in shape with a length to width ratio of about 2.5:1.0 having two elongated slots extending upward from the bottom edge and two elongated slots extending downward from the top side near the left and right side edges having a width of about the thickness of the construction plate and a length of about one-fifth to about one-seventh the length of the plate.

Construction plate L25 is similar to L24 having two rectangular openings about the center of the plate about equidistant from each other.

Construction plates L21 through L25 are used to create the wall columns of the organization storage and display systems.

Each of the construction plates may have electronic elements that provide electricity to operate desired devices in an organizational or display system such as lights or speakers. As such, the construction plates may have conduits that provide electrical wiring as well as connectors that allow items such as these to be operational. During construction of the plates their general configuration is cut from sheet material. The electrical conduits may be routed into the surface before the desired surface is applied encasing the conduits. Connector elements may be provided so that each construction plate may be able to be connected to one or more constructions plates in the system. The construction plates may also be configured with outlets to plug in other electronic equipment for charging or operation. These may include outlets for desk top computers, laptop computers, tablets, cellular phones, battery chargers, extension cords or surge protectors. Construction plates containing a controller for the operation of lights, a router for transferring information from one location to another, an antenna for receiving or transmitting signals, a data communications relay system and or a WiFi connectivity hub. These devices can be integrated into the body of the construction plates by providing an appropriate space by cutting or routing a portion of the construction plate and placing the devices within before covering with the desired surface coating in the construction plate. One or more control panels may also be integrated into the construction plates so that a user may control the devices that have been incorporated into that particular organizational or display system.

Using the construction plates of the present invention a trade show display may be assembled in a multitude of configurations based on the needs of the user and the restrictions of trade show convention offerings. Most trade show footprints are leased to exhibitors in 10 foot by 10 foot real estate. In some cases, there are smaller spaces but usually no smaller than 10 foot by 5 foot. Another use for this display is at roadshows for manufacturers presenting their product at retail locations on a short-term basis to demonstrate their product to store managers and in some cases retail store customers. In the case of roadshows, the foot print may be smaller than the standards of convention centers. In this case, the space available to display may only be 3 feet by 5 feet. In any of these cases, the present invention display may be constructed in 18 inch by 18 inch support structures for both the wall columns and the table top columns. Both columns have the same foot print and create the majority of the structural composition of the display system. The plates that construct the entire display slot together and allow the user to utilize all or some of the construction plates to increase the height of a column. Usually the maximum height of a trade show booth is 8 feet unless the convention allows for a concession. In that case, the additional distance is usually only allowing graphics for additional branding. The present invention system may have a cut out in the plate resting on the top of the wall column to insert any rigid material that can be printed on for the purposes of offering more branding beyond the 8 foot high column. In the case of an outdoor event where a canopy is required, the user may remove one of the larger plates in the column to reduce the overall height to 6 feet allowing the booth to sit under an 8 foot pop up canopy. Wall columns in the 8 foot high configuration may be comprised of 5 unique plates and a total 10 plates. Six foot high wall columns may be comprised of 5 unique plates and a total of 8 plates. Additionally, the table top column in the 33.5 inches height may be comprised of 5 unique plates and a total of 7 plates. The merchandising components of the display system are what connect the wall columns and the table top columns together while offering a platform for merchandising product.

All of the plates that comprise the wall columns and table top columns as well as the merchandising plates of the booth are generally about 18 inches to about than 42 inches. This allows every part to fit in a crate for easy transport. Additionally, the slots that join the plates together have depth ranging from about 7% to about 55% of the longest part. In the case of the smallest ratio, the slot for the top of booth graphics may be only 3 inches on the longest part which is 42 inches. One of the largest ratios has an 11.4 inch slot on the 21 inch long by 18 inch part that is the base plate for both the table top column and the wall column. Each joining slot has specific depth to create stability and allow the booth to be constructed to an 8 foot or 6 foot height by adding or subtracting plates. The shorter slots on the edges of the plates allow the columns and table tops to be joined together with the table top connector plate.

In one configuration, the two 42 inch long and 18 inch plates that face each other on each wall column may have several specific cutout shapes that provide ways for adding merchandising solutions. These cutouts may be about 6 inches wide by about 10 inches tall and provide a resting place for the 42 inch long shelves. Additionally when present, two ¼ inch holes on either side of the 6×10 inch cutouts may enable the user to insert shelf support tabs to add additional shelving for companies with smaller products. The insert tabs are pushed into the hole and provide a stable surface for a 36 inch shelf to be added. The longer 42 inch by 10 wide shelves may have 2 notches at 2 inches and 4 inches from either end. They allow for the distance between the columns to expand and contract. This longer shelf would sit inside the 6×10 inch cutout. Having the notches on the 42 inch shelf may be important in the event that a neighboring exhibitor erects their display partially into your space. In addition, the ability to contract and expand is helpful in the event that there is a cable running under the carpeting of the convention center or another obstruction is present when exhibiting at a convention center. Not only does the shelf provide structural support by fastening the 2 columns together it also enables the user to display product at a multitude of heights. This display system offers at least 8 shelves per wall between 2 columns. These shelves also provide additional stability of the entire structure.

Another cutout shape in the construction plate is the 3.5 inch slot at the top center of the plate. This slot allows the user to insert a ½ inch thick material between 2 columns. This printed panel will serve as additional branding and can rest on the slots of 2 columns spanning a distance of about 4 feet.

Another cutout is the slot on the outer edges which provides an area for a plate to be inserted perpendicularly to provide a shelf on the front of the column. In addition to adding shelves to the front of the column the slot allows the table top connector plate to slide into a corresponding slot on one of the table top column parts. Connecting this plate to the slots on the same plane not only provides stability for the column and the table top but also provides a merchandising solution.

Another cutout in the 42×18 inch wall construction plate may be a 1 inch circular cutout, keyhole aperture, extending from the 6×10 inch cutout. This circular cutout enables the user to connect a 1 inch×1 inch dowel between 2 columns thereby providing a garment pole to merchandise clothing on hangars.

Another cutout in the 42×18 inch wall column plate is the 2 circular cutouts in the back side of the top and bottom of the plate. These cutouts enable the user to insert a 40 inch×1.5 inch dowel into each cutout and connect the 2 columns. The purpose of the dowels is to insert the dowels into sewn pockets of a fabric banner to create a closed back wall and or branding opportunity in between the 2 columns.

The construction plates may have cutouts for a variety of reasons two of these reasons are to reduce the overall weight of each plate and to provide the utility function of connecting support structures, merchandising a variety of products and adding graphics for company branding.

Some configurations that may be created with the systems plates are provided as follows. A 6 foot tall 5 foot wide by 3 foot deep display configuration may be comprised of 2 wall columns with an 18 inch footprint and one table top pedestal with an 18 inch foot print. The number of parts in this configuration may be about 28 plates. Eight for each wall column, 7 plates for the table top pedestal and five 42 inch×10 inch shelves. This configuration will fit inside a crate with an inner dimension of 18 inches in width by 42 inches in length by 12 inches in height.

A 6 foot tall 5 foot wide by 5 foot deep display configuration may be comprised of 2 wall columns with an 18 inch footprint, one 33.5 inch×18 inch table top connector and one table top pedestal with an 18 inch foot print. The number of parts in this configuration may be about 29 plates. Eight plates for each wall column, 7 plates for the table top pedestal, 1 table top connector and five 44 inch×10 inch shelves. This configuration will fit inside a crate with an inner dimension of 18 inches in width by 42 inches in length by 12 inches in height.

An 8 foot tall 10 foot wide by 5 foot deep trade show configuration with all shelves may be comprised of 3 wall columns with an 18 inch footprint, 2 table top connectors and 2 table top pedestals with an 18 inch foot print and 10 shelves. The number of parts in this configuration may be 56 plates. Thirty plates for each wall column, 14 plates for the table top pedestals, 2 table top connector and 10, 42 inch×10 inch shelves. This configuration will fit inside a crate with an inner dimension of 18 inches in width by 42 inches in length by 12 inches in height.

An 8 foot tall 10 foot wide by 10 foot deep trade show configuration with all shelves may be comprised of 3 wall columns with an 18 inch footprint, 4 table top connectors and 4 table top pedestals with an 18 inch foot print and 10 shelves. The number of parts in this configuration may be 72 plates. Thirty plates for the wall column, 28 plates for the table top pedestals, 4 table top connector and 10 shelves. This configuration will fit inside a crate with an inner dimension of 18 inches in width by 42 inches in length by 22 inches in height. This configuration comprised of a 2 sided vertical grade laminate on poplar plywood would weigh less than 300 pounds. This configuration comprised of a Baltic birch plywood would weigh approximately 400 pounds.

An 8 foot tall 10 foot wide by 10 foot deep trade show configuration with all modular slatwall may be comprised of 3 wall columns with an 18 inch footprint, 4 table top connectors and 4 table top pedestals with an 18 inch foot print and 6 slatwall support runners and 15 (6 inch in width×32 inch in length) slatwall. The number of parts in this configuration may be 62 plates. Thirty plates for the wall columns, 28 plates for the table top pedestals, 4 table top connectors. This configuration will fit inside a crate with an inner dimension of 18 inches in width by 42 inches in length by 28 inches in height.

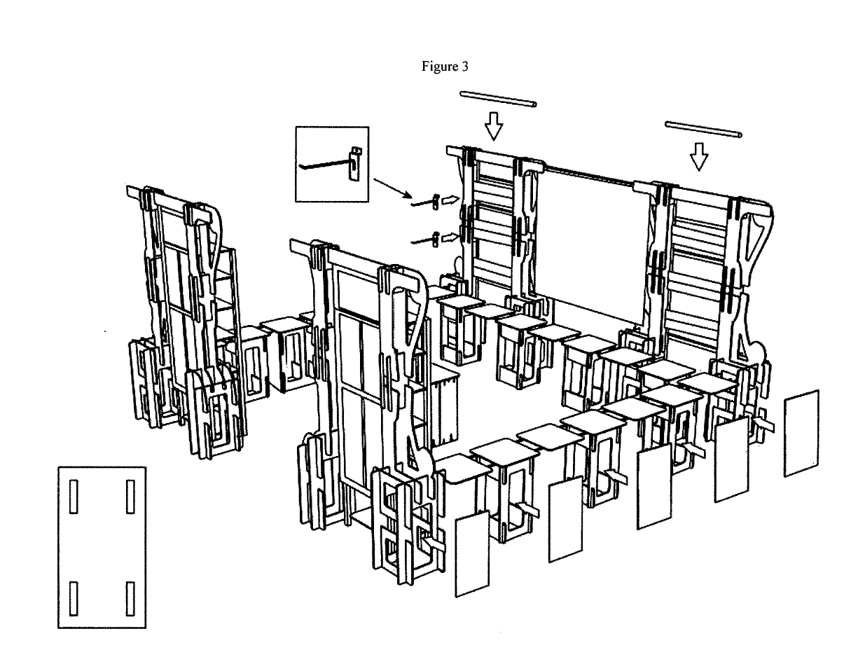

An 8 foot tall 20 foot wide by 10 foot deep trade show configuration with all shelves may be comprised of 5 wall columns each with an 18 inch footprint, 4 table top connectors and 4 table top pedestals each with an 18 inch foot print and 20 shelves. The number of parts in this configuration may be 108 plates. Fifty plates for the wall columns, 28 plates for the table top pedestals, 4 table top connector and 20 shelves. This configuration will fit inside a crate with an inner dimension of 18 inches in width by 42 inches in length by 30 inches in height. This configuration may be comprised of a 2 sided vertical grade laminate on poplar plywood would weigh less than 500 pounds. An example of a 20 foot by 10 foot display booth is shown in FIG. 3. This configuration comprised of a Baltic birch plywood would weigh approximately 700 pounds.

An 8 foot tall 20 foot wide by 20 foot deep trade show configuration with all shelves is essentially two 8 foot tall 20 foot wide by 10 foot deep booths facing each other. The number of parts in this configuration may be 216 plates. One-hundred plates for the wall columns, 56 plates for the table top pedestals, 8 table top connector and 40 shelves. This configuration will fit inside 2 crates with an inner dimension of 18 inches in width by 42 inches in length by 30 inches in height. This configuration comprised of a 2 sided vertical grade laminate on poplar plywood would weigh less than 1000 pounds. This configuration comprised of a Baltic birch plywood would weigh approximately 1400 pounds.

There are many more configurations possible like a 10×30 foot or 10×40 foot layout. This system enables you to add wall columns and table tops which are connected by merchandising solutions to fill any footprint available in convention centers or outdoor events.

Other embodiments of the present invention include: self-interlocking tabs that snap and secure the parts together; shelving and tabletops that can be connected to the walls and frame via the tab and slot system; magnets integrated into the plates to strengthen the connections between the supporting structure and display surfaces like shelving and table tops; garment poles that can be connected to opposing walls via recessed design features to provide a utility for merchandising apparel on hangars; peg holes that can be extruded from the structure's wall parts to provide a utility for packaged products; horizontal L-shaped recesses in the wall parts that can be extruded to provide a utility for inserting shelving that is constructed with complimentary fitting pieces that lock into place and provide a stable surface for merchandising product (this system is sometimes referred to as slatwall); aesthetic cover-panels (that come in a variety of materials, colors, and patterns) that secure onto the walls and frame by fitting the tabs onto matching recessed extrusions on the back of the plates to conceal the underlying tab-and-slot structure; light weight aesthetic covers or plugs (that come in a variety of materials, colors, and patterns) that fit into the cut outs of the flat plate parts to provide an option to create a solid plate look and offer additional branding opportunities; the ability to hang printed banners on the outside and inside of the display booth for the purposes of company branding; an upward hook feature at the top of the booth structure that a banner attached to a pole can rest on horizontally as well as downward facing hook features at the base of the of the booth structure that can hook under to ultimately fasten a tall banner in place to the side of the booth structure; removable covers in the structure that will reveal holes for mounting AV supplies such as flat panel monitors as well as room for electrical wires to run through; a container that houses the disassembled display booth to have wheels so that the display booth can be rolled by one person; magnets to be embedded in the flat panels so that fabric banners can be fastened to the structure for additional branding; flat plates that have speakers embedded in them; materials that may be laid over the openings of the flat plates to allow light to show through as to backlight the structure or any branding graphics; integrated Lazy Susan in table top flat plates (essentially sandwiching the connecting flat plate and the table top surface with a Lazy Susan ball bearing mechanism for the purposes of creating a spinning display system); flat plates having an extruded conduit to allow for an electrical system to run through it and a connecting system in the slots of each plate so that when the plates are slotted together they form an electrical current that will power the entire structure for a variety of functions like lighting and sound, providing one or more plug elements for connecting devices to the construction plate that require electricity to operate; flat plates having integrated electronics such as one or more controllers for operating the electronic systems integrated into the plates, a router for transferring information, an antenna for receiving or transmitting signals, a data communications relay system and/or a WiFi connectivity hub for connecting, relaying or receiving data transmissions from other communication devices as well as connectors to allow the user to monitor, collect manipulate, and transmit data (e.g., integrating a cellular phone into a construction plate having connectors to other plates to control systems in those plates); hanging slatwall supports on the inner side of each column (i.e., the slatwall hangers have a recessed runner to drop the slatwall pieces into to secure them in place. There is an option to extend the support from the top of the wall column to the floor by using a connector piece that is fastened in a number of ways like a dovetail or pin system. This would allow the user to adjust the amount of slatwall used on a given wall); a container that houses the assembled display booth to have a recess, groove or any other means to place the same flat plates as used for the booth structure to cover the crate and make it a useful surface to convert into a table top thereby allowing the crate to remain in the booth; an interlocking dove tail or pin to secure the shelves or table top connectors in place; and multitude of level holes in the flat plates which would be used for inserting shelf support pegs that will allow additional shelves to be added to the structure.

It will be appreciated that details of the foregoing embodiments, given for purposes of illustration, are not to be construed as limiting the scope of this invention. Although several embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention. Further, it is recognized that many embodiments may be conceived that do not achieve all of the advantages of some embodiments, particularly of the preferred embodiments, yet the absence of a particular advantage shall not be construed to necessarily mean that such an embodiment is outside the scope of the present invention.

I claim:

1. A construction plate comprising:
A flat sheet of generally square or rectangular material having a length to width ratio of about 0.5:1.0, about 1.0:1.0, about 1.0:2.0 or about 1.0:5.0 and having a top edge, a bottom edge, a left side edge, a right side edge, a left side, a right side, a top side and a bottom side, wherein said flat sheet has at least one opening about its center that is square or rectangular in shape and is of a size that occupies about 10% to about 30% of the area of said flat sheet, wherein said top edge has at least two elongated slots near said left and right side edges, said slots being the same thickness as said flat sheet and having a length of about 1/10 to about ½ the length of said flat sheet, wherein said top edge has X indentations having a depth of about the thickness of said flat sheet and a length of about ¼ to about ⅓ the width of said top edge, wherein X=0 or 1, wherein said bottom edge has Y elongated slots near said left and right side edges, said slots being the same thickness as said flat sheet and having a length of about 1/10 to about ½ the length of said flat sheet, wherein Y=0 or 2, wherein said left side edge and said right side edge independently have Z slots, said slots being the same thickness as said flat sheet and having a length of about 1/20 to about ⅕ the width of said flat sheet, wherein Z=0, 1, 2, 3, 4, 5, 6, 7, 8, 9 or 10, said left side and said right side independently have P apertures near the corner of the top edge and said left side and/or right side edges and near the corner of said bottom edge and said left side and/or right side edges, wherein said apertures are from about 2.0 cm to about 6.0 cm, wherein P=0 or 1, and wherein said at least one opening has Q keyhole shaped apertures extending toward said bottom edge of said flat sheet, wherein Q=0, 1 or 2 and wherein said top edge has R keyhole shaped apertures extending toward said bottom edge of said flat sheet, wherein R=0 or 1.

2. A construction plate according to claim 1, wherein said plate further comprises an electrical system, wherein said electrical system has an inlet for receiving electrical current, one or more plug elements for connecting devices to said construction plate that require electricity to operate and an outlet for electrical connectivity with one or more other construction plates.

3. A construction plate according to claim 2, wherein said plate further comprises one or more lights or one or more speakers, wherein said one or more lights or one or more speakers are affixed to or integrated within said plate.

4. A construction plate according to claim 1, wherein said plate further comprises an electrical system having one or more adapters for connecting one or more desk top computers, one or more laptop computers, one or more tablets, one or more cellular phones, one or more battery chargers, one or more extension cords or one or more surge protectors.

5. A construction plate according to claim 2, wherein said electrical system further comprises one or more of controllers, routers, antennas, data communications relay systems and or a WiFi connectivity hubs.

6. A construction plate according to claim 1, wherein said plate further comprises a magnetically susceptible surface or has one or more magnets embedded within said plate.

7. A construction plate according to claim 1, further comprising a translucent cover that fits within said at least one opening.

8. An organizational storage or display system comprising:
a plurality of construction plates that are connected together in a desired configuration at 90 degrees to one another by slot in slot connectors;
S table tops, wherein the edges of said table top is inserted into a Z slot of a construction plate and wherein S=0 to 5;
T pedestal tops, wherein said pedestal tops have at least four apertures or groove indentations, wherein said apertures or groove indentations have a length of about 2.5 to about 7.5 centimeters and a width slightly larger than the thickness of said construction plate, the region between any two apertures that have a common axis to be received by said X indentations of a construction plate and wherein T=0 to 10;
N shelves, wherein said shelves have a front end a back end a left side and a right side, wherein each of said sides contains a notched adapter, wherein said notch is slightly larger than the thickness of said construction plate, wherein said notched adapter fits through said at least one opening and engages the edges of said at least one opening orienting said shelf in a horizontal orientation parallel with the ground, wherein N=0 to 30;
M slat wall supports, said slat wall supports having a groove along its length and affixed to said construction plate so that said slat wall support is oriented perpendicular to the ground wherein M=0, 2, 4, 6, 8 or 10; and
K wall slats, said wall slats having a thickness slightly thinner than said groove in said slat wall supports, wherein K=2 to 100.

9. An organizational storage or display system according to claim 2, further comprising J joice supports wherein said joice supports have an upper side, a lower side, a first end side and a second end side, wherein said joke support has at least two notches on its lower side for receiving said top edge of said construction plate and wherein J=0 to 10.

10. An organizational storage or display system according to claim 7, wherein said table top or said pedestal top further comprises a revolving platform.
